(19) United States
(12) Patent Application Publication
(10) Pub. No.: US 2007/0280385 A1
(43) Pub. Date: Dec. 6, 2007

(54) Method and apparatus of receiving signals and wireless multimode wideband receiver

(75) Inventor: Chun-Ming Chen, Hsinchu City (TW)

Correspondence Address: RABIN & Berdo, PC, 1101 14TH STREET, NW, SUITE 500, WASHINGTON, DC, 20005, US

(73) Assignee: BenQ Corporation, Taoyuan Shien (TW)

(21) Appl. No.: 11/806,066

(22) Filed: May 29, 2007

(30) Foreign Application Priority Data
May 30, 2006 (TW) 95119269

(51) Int. Cl. H03D 1/04

(52) U.S. Cl. 375/346

(57) ABSTRACT

A method of receiving a target signal existing in a wideband signal. The method includes the steps of receiving the wideband signal, removing the target signal from the wideband signal to obtain an interference signal, transforming the interference signal into an inverse interference signal, and finally combining the wideband signal with the inverse interference signal to get the target signal.

This application claims the benefit of Taiwan application Serial No. 95119269, filed May 30, 2006, the subject matter of which is incorporated herein by reference.

### BACKGROUND OF THE INVENTION

1. Field of the Invention

The invention relates in general to a method and an apparatus of receiving signals and a wireless multimode wideband receiver, and more particularly to a high-efficiency method and a high-frequency apparatus of receiving signals and a wireless multimode wideband receiver.

2. Description of the Related Art

Recently, the wireless communication technology is developed, with the extremely high speed, from a single analog communication system, which only can carry the basic audio and text messages in the early stage, to a digital communication system, which is complicated and can transfer a lot of multimedia messages. In addition, the diversified communication protocols are also created to satisfy the diversified communication requirements. Nowadays, the more popular communication standards, such as PHS, GSM, GPRS, WCDMA, CDMA2000 and WLAN, have been used all over the world. However, different communication standards are used in different areas, so people cannot use the single communication apparatus with the single communication standards to communicate with others all over the world. In order to overcome this inconvenience, a multimode wireless communication device capable of operating under different communication protocols is developed.

The multimode wireless communication device includes a multimode wireless receiver for receiving and demodulating different types of communication signals under the different communication standards and different frequencies. The architecture of the multimode wireless receiver progresses with the development of the technology. The conventional architecture of the super heterodyne or the dual conversion requiring the intermediate frequency stage (IF stage) has been recently replaced with the architecture of the direct conversion, the intermediate frequency (IF) or the low intermediate frequency (Low IF), and the received signal is directly converted from the radio frequency to the baseband. Because the intermediate frequency stage is skipped, the architecture of the direct conversion has the fewer components as compared with the architecture of the dual conversion.

FIG. 1 (Prior Art) is a block diagram showing a conventional multimode wireless receiver 10. Referring to FIG. 1, the multimode wireless receiver 10 includes an antenna 12, a wireless multimode wideband receiver 14, a quadrature demodulator 16 and a digital baseband processor 18. The antenna 12 receives a wideband signal from the open space and transfers the wideband signal to the wireless multimode wideband receiver 14. The wireless multimode wideband receiver 14 amplifies the wideband signal, filters out an interference signal, such as noise, from the wideband signal to obtain a target signal, and transfers the target signal to the quadrature demodulator 16. The quadrature demodulator 16 converts the received target signal from the radio frequency to the baseband and separates the signal and enters two quadrature paths, which are I path and Q path. The quadrature demodulator 16 also respectively converts the I analog signal and the Q analog signal into digital target signals to be transferred to the digital baseband processor 18. The digital baseband processor 18 further processes the digital target signals so as to extract the data carried by the digital target signals. In addition, the digital baseband processor 18 also provides control signals, such as a mode selection signal, a low-noise amplifier gain control signal and a demodulator gain control signal.

FIG. 2 (Prior Art) shows the architecture of the conventional wireless multimode wideband receiver 14. Referring to FIG. 2, the wireless multimode wideband receiver 14 includes an antenna switching module 20 and a receiver switching module 26 for guiding the received wideband signal to be transferred through the corresponding path according to the communication protocol of the target signal. A band pass filter (210, 220, 230, 244 or 254) for filtering the interference signal and a low-noise amplifier (212, 222, 232, 242 or 252) for amplifying the target signal are disposed corresponding to each signal path, and the target signal passes while the interference signal is filtered out. In addition, if the target signal is a WCDMA signal or a CDMA2000 signal, the target signal needs to be transmitted and received synchronously. So, a duplexer (240 or 250) is needed to prevent the transmitted signal from leaking into the receiver.

In addition, the target signal falls within the frequency band of the band pass filter (210, 220, 230, 244 or 254), and the interference signal may be divided into the interference signal within the frequency band and the interference signal outside the frequency band. The interference signal outside the frequency band falls outside the frequency band of the band pass filter (210, 220, 230, 244 or 254) and is filtered out. The interference signal within the frequency band falls within the frequency band of the band pass filter (210, 220, 230, 244 or 254) and cannot be filtered. Because the interference signal within the frequency band passes through the active device, such as the low-noise amplifier, the interference signal within the frequency band causes the non-linear distortion in the active device if the interference signal within the frequency band is strong enough. The distorted signals enter the frequency band of the target signal and become the noise so that the efficiency of the multimode wireless receiver 10 is lowered. In addition, the ideal high-frequency band pass filter cannot be easily designed, thereby bring the confusion to the engineers.

### SUMMARY OF THE INVENTION

The invention is directed to a method and an apparatus of receiving signals, and a wireless multimode wideband receiver, which transform an interference signal into an inverse interference signal and combine a wideband signal with the inverse interference signal to get a target signal so as to eliminate the non-linear distortion caused by the interference signal and enhance the efficiency of the wireless multimode wideband receiver.

According to a first aspect of the present invention, a method of receiving a target signal existing in a wideband signal is provided. The method includes the steps of receiving the wideband signal, removing the target signal from the wideband signal to get an interference signal, transforming the interference signal into an inverse interference signal and combining the wideband signal with the inverse interference signal to get the target signal.

According to a second aspect of the present invention, a signal receiver for receiving a target signal existing in a wideband signal is provided. The wideband signal has a first bandwidth. The target signal occupies a second bandwidth in the wideband signal. The signal receiver includes a circulator, a band pass filter, an inverter and a combiner. The circulator receives the wideband signal and has a first output terminal and a second output terminal. The band pass filter is coupled to the first output terminal of the circulator. The target signal in the wideband signal can pass through the band pass filter, and signals that cannot pass through the band pass filter form an interference signal to be fed into the first output terminal. The inverter, which is coupled to the second output terminal of the circulator, receives the interference signal from the second output terminal and transforms the interference signal into an inverse interference signal. The combiner combines the wideband signal with the inverse interference signal to get the target signal.

According to a third aspect of the present invention, a wireless multimode wideband receiver is provided. The wireless multimode wideband receiver includes an antenna switching module, a first duplexer, a second duplexer, a receiver switching module, a signal receiver and a wideband low-noise amplifier. The antenna switching module receives a wideband signal including a target signal. The first duplexer is coupled to the antenna switching module. The second duplexer is coupled to the antenna switching module. The receiver switching module, which is coupled to the antenna switching module, the first duplexer and the second duplexer, receives the wideband signal from the antenna switching module, the first duplexer or the second duplexer. The signal receiver, which is coupled to the receiver switching module, extracts the target signal from the wideband signal and outputs the target signal. The wideband low-noise amplifier, which is coupled to the signal receiver, amplifies the target signal into an amplified target signal.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a block diagram showing a conventional multimode wireless receiver.

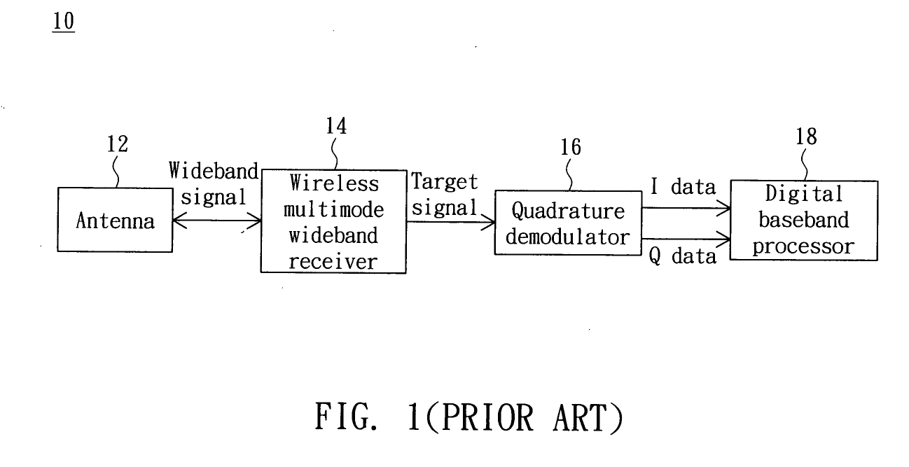

FIG. 2 (Prior Art) shows the architecture of the conventional wireless multimode wideband receiver.

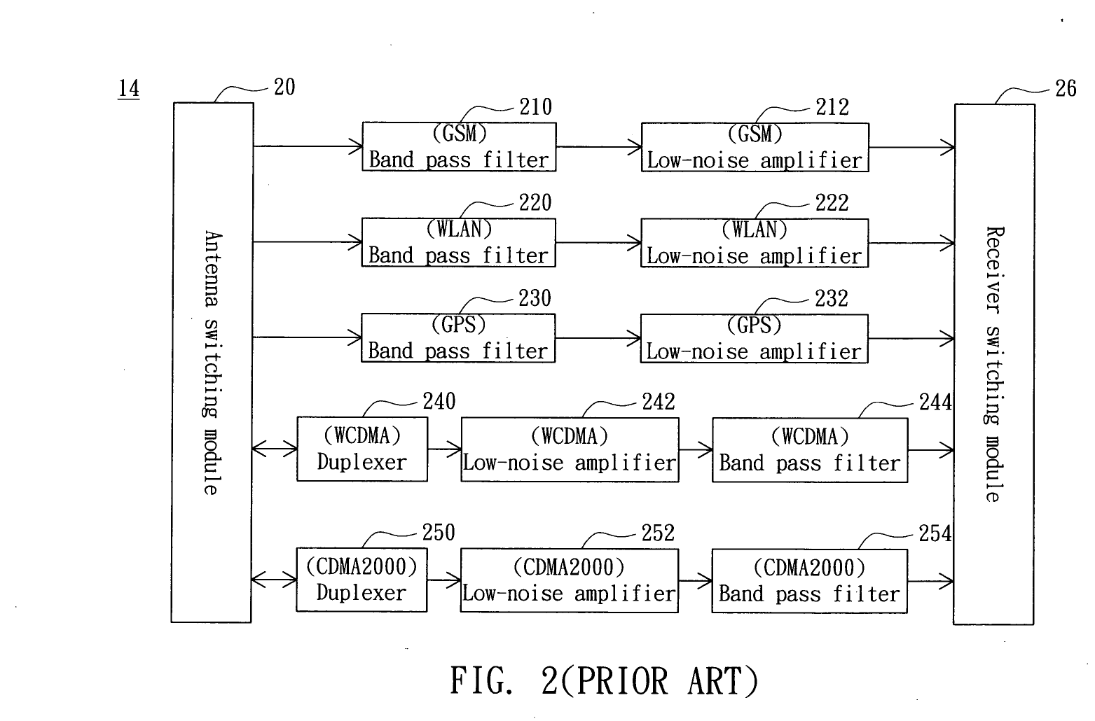

FIG. 3 is a flow chart showing a signal receiving method according to a preferred embodiment of the invention.

FIG. 4 is a block diagram showing a signal receiver according to the preferred embodiment of the invention.

FIG. 5 is a block diagram showing a wireless multimode wideband receiver according to the preferred embodiment of the invention.

FIG. 6 is a block diagram showing a software set wireless receiver according to another embodiment of the invention.

### DETAILED DESCRIPTION OF THE INVENTION

The invention provides a method and an apparatus of receiving signals and a wireless multimode wideband receiver, which transform an interference signal into an inverse interference signal and combine a wideband signal with the inverse interference signal to get a target signal so as to eliminate the non-linear distortion caused by the interference signal and enhance the efficiency of the wireless multimode wideband receiver.

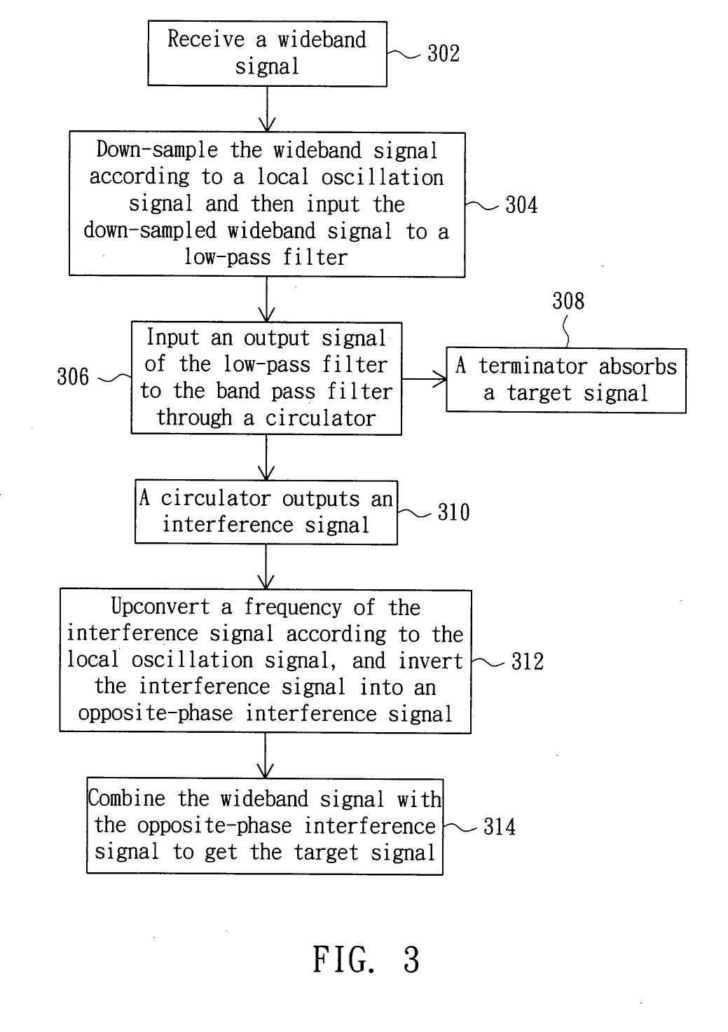

FIG. 3 is a flow chart showing a signal receiving method according to a preferred embodiment of the invention. As shown in FIG. 3, this signal receiving method receives a target signal existing in a wideband signal. The wideband signal has a first bandwidth, the target signal has a second bandwidth, and the first bandwidth is greater than the second bandwidth. In addition, the target signal has a center frequency in the wideband signal.

First, in step 302, the wideband signal is received. Next, in step 304, the wideband signal is down-sampled according to a local oscillation signal and then inputted to a low-pass filter, wherein the frequency of the local oscillation signal is lower than the center frequency possessed by the target signal in the wideband signal. Then, in step 306, an output signal of the low-pass filter passes through a circulator and is then inputted to a band pass filter. The bandwidth that can pass through the band pass filter is greater than the second bandwidth and smaller than the first bandwidth. The target signal passes through the band pass filter, and the interference signal does not pass through the band pass filter.

Then, in step 308, the target signal passing through the band pass filter is absorbed by a terminator coupled to the band pass filter. Next, in step 310, the interference signal is outputted from one terminal of the circulator. Then, in step 312, the interference signal is up-sampled according to the local oscillation signal and inverted into the inverse interference signal. Finally, in step 314, the wideband signal and the inverse interference signal are combined to get the target signal.

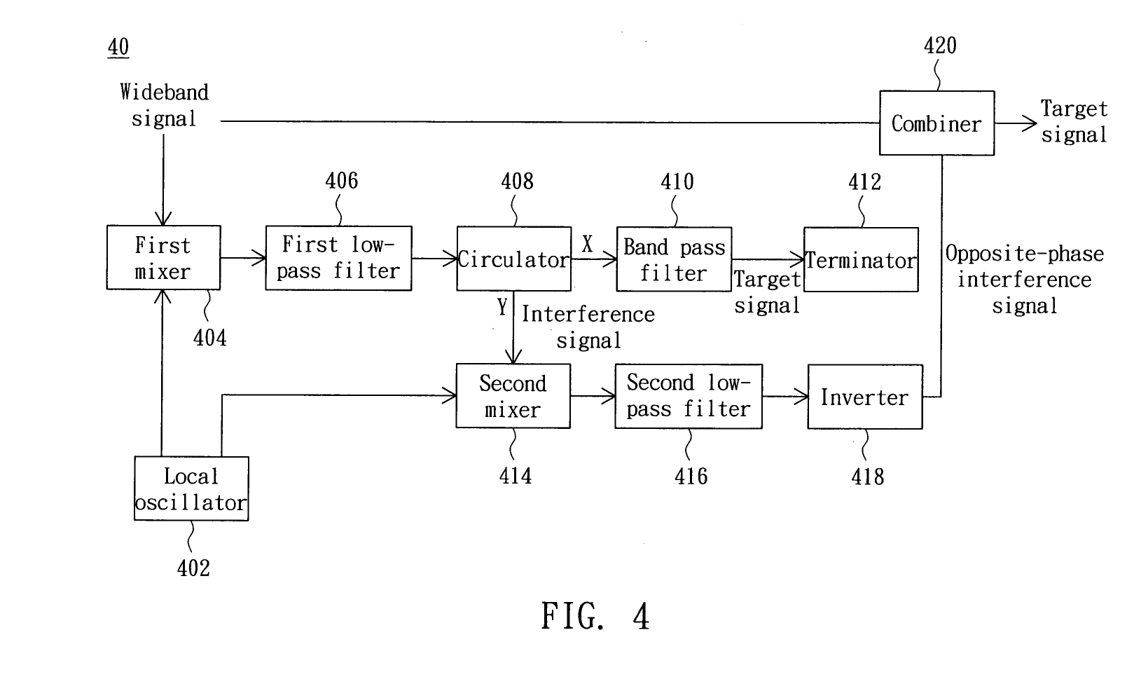

FIG. 4 is a block diagram showing a signal receiver 40 according to the preferred embodiment of the invention. As shown in FIG. 4, the signal receiver 40 is for receiving the target signal existing in the wideband signal having the first bandwidth. The target signal occupies the second bandwidth in the wideband signal, and the first bandwidth is greater than the second bandwidth. In addition, the target signal has the center frequency in the wideband signal.

The signal receiver 40 includes a local oscillator 402, a first mixer 404, a first low-pass filter 406, a circulator 408, a band pass filter 410, a terminator 412, a second mixer 414, a second low-pass filter 416, an inverter 418 and a combiner 420. The local oscillator 402 generates a local oscillation signal having a frequency lower than the center frequency possessed by the target signal in the wideband signal. The first mixer 404 down-samples the wideband signal according to the local oscillation signal. The first low-pass filter 406 coupled to the first mixer 404 receives the down-sampled wideband signal and outputs the down-sampled wideband signal to the circulator 408.

The circulator 408 having a first output terminal X and a second output terminal Y receives the down-sampled wideband signal from the first low-pass filter 406. The band pass filter 410 is coupled to the first output terminal of the circulator 408, and a bandwidth that may pass through the band pass filter 410 is greater than the second bandwidth and smaller than the first bandwidth. Thus, the target signal in the wideband signal passes through the band pass filter 410, and the other signals that cannot pass through the band pass filter 410 form the interference signal, which is fed to the first output terminal X of the circulator 408 and then outputted from the second output terminal Y of the circulator 408. The terminator 412 coupled to the band pass filter 410 is for absorbing the target signal.

The second mixer 414 coupled to the second output terminal Y of the circulator 408 upconverts the frequency of the interference signal according to the local oscillation signal. The second low-pass filter 416 receives the upconverted interference signal and outputs the upconverted interference signal to the inverter 418. The inverter 418 receives the interference signal and transforms the interference signal into the inverse interference signal. The combiner 420 combines the wideband signal with the inverse interference signal to get the target signal.

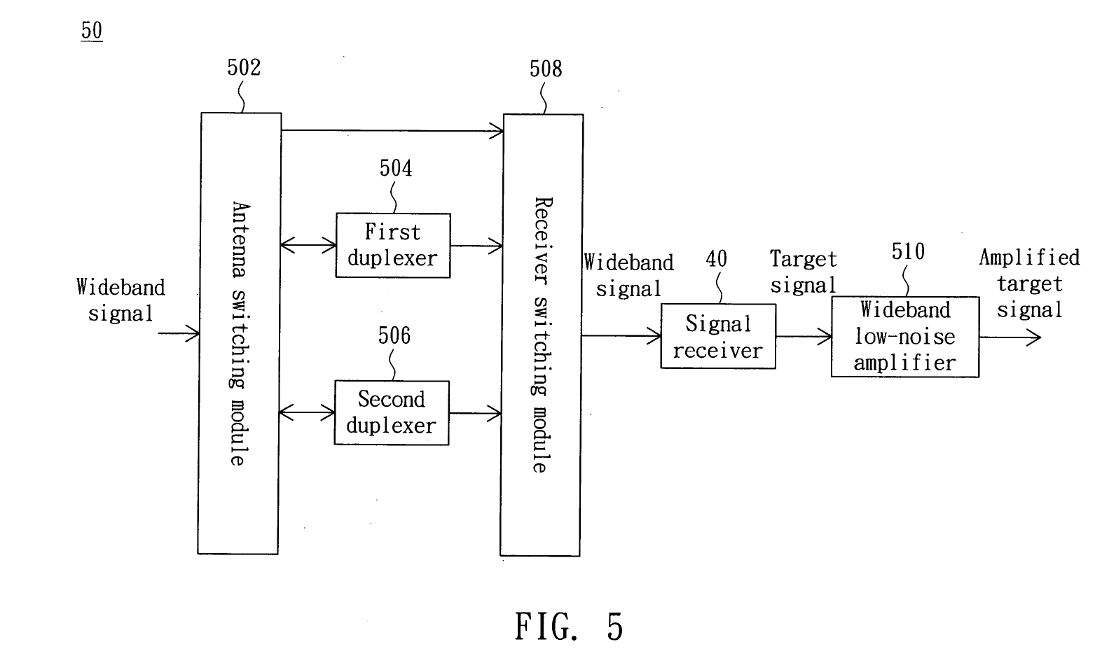

FIG. 5 is a block diagram showing a wireless multimode wideband receiver 50 according to the preferred embodiment of the invention. Referring to FIG. 5, the wireless multimode wideband receiver 50 includes an antenna switching module 502, a first duplexer 504, a second duplexer 506, a receiver switching module 508, the signal receiver 40 and a wideband low-noise amplifier 510. The antenna switching module 502 receives a wideband signal, which includes a target signal and has a first bandwidth. The target signal occupies a second bandwidth in the wideband signal, and the first bandwidth is greater than the second bandwidth. The first duplexer 504 is coupled to the antenna switching module 502 and is a WCDMA duplexer. The second duplexer 506 is coupled to the antenna switching module 502, and the second duplexer 506 is a CDMA2000 duplexer.

The receiver switching module 508, which is coupled to the antenna switching module 502, the first duplexer 504 and the second duplexer 506, receives the wideband signal from the antenna switching module 502, the first duplexer 504 or the second duplexer 506. The antenna switching module 502 and the receiver switching module 508 determine a transmitting path of the wideband signal according to the target signal. The WCDMA signal and the CDMA2000 signal have to be transmitted and received synchronously. So, the wideband signal is transmitted to the receiver switching module 508 through the first duplexer 504 when the target signal is the WCDMA signal, and the wideband signal is transmitted to the receiver switching module 508 through the second duplexer 506 when the target signal is the CDMA2000 signal, or otherwise the antenna switching module 502 directly transmits the wideband signal to the receiver switching module 508. In this case, the oscillation frequency of the local oscillator 402 may also be adjusted according to the selected target signal.

The signal receiver 40 coupled to the receiver switching module 508 extracts the target signal from the wideband signal and then outputs the target signal. The block diagram of the signal receiver 40 is depicted in FIG. 4, and the function of the signal receiver 40 has been mentioned hereinabove, so detailed descriptions thereof will be omitted. The wideband low-noise amplifier 510 coupled to the signal receiver 40 receives the target signal and amplifies the target signal into an amplified target signal.

The method and the apparatus for receiving the signals and the wireless multimode wideband receiver utilize the signal receiver to transform the interference signal into the inverse interference signal, combine the inverse interference signal with the wideband signal to obtain the target signal, and filter out all the interference signals so that a lot of band pass filters and a lot of low-noise amplifiers may be saved, and the cost may be reduced. In addition, the passed band set by the band pass filter in the signal receiver is smaller, so all the interference signals have been filtered out before entering the wideband low-noise amplifier. Consequently, the non-linear distortion that may be generated by the interference signal on the active device can be eliminated, and no noise may occur so that the efficiency of the wireless multimode wideband receiver can be enhanced and thus the efficiency of the multimode wireless receiver can be enhanced. In addition, when the overall system has no interference signal, the function of the signal receiver may be disabled to save the power.

In addition, the wireless multimode wideband receiver may also be applied to a software set wireless receiver, which may process multiple communication protocols and multiple frequency bands under the same hardware through the software setting. The software set wireless receiver may be upgraded through the simple software downloading, and the wireless feature and the function can be further reset. The software set wireless receiver may serve as a mobile telephone, or a wireless network device for downloading the mail or receiving the GPS signal. In order to achieve the above-identified objects, the radio frequency end of the software set wireless receiver has the very wide bandwidth and the very high sensitivity.

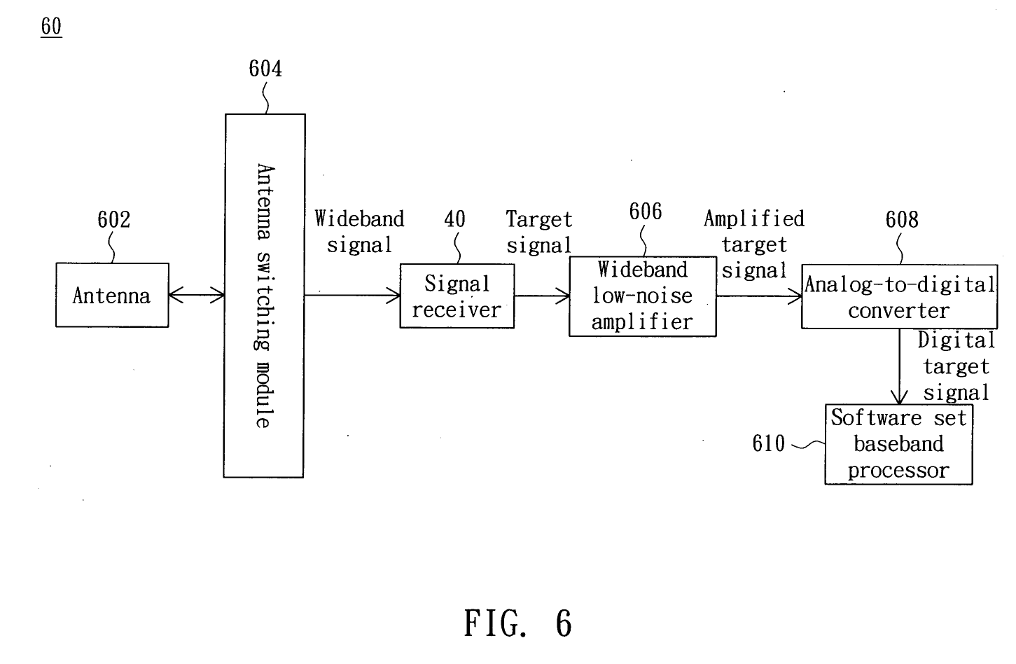

FIG. 6 is a block diagram showing a software set wireless receiver 60 according to another embodiment of the invention. Referring to FIG. 6, the software set wireless receiver 60 includes an antenna 602, an antenna switching module 604, the signal receiver 40, a wideband low-noise amplifier 606, an analog-to-digital converter 608 and a software set baseband processor 610. The antenna 602 and the antenna switching module 604 receive a wideband signal. The signal receiver 40 and the wideband low-noise amplifier 606 remove the interference signal in order to achieve the wideband requirement, and the signal receiver 40 outputs the target signal by way of adjusting the oscillation frequency by the local oscillator 402. The wideband low-noise amplifier 606 outputs the amplified target signal. The analog-to-digital converter 608 coupled to the wideband low-noise amplifier 606 transforms the amplified target signal into a digital target signal. The software set baseband processor 610 coupled to the analog-to-digital converter 608 receives and computes the digital target signal so as to process multiple communication protocols according to the software set function.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of receiving a target signal existing in a wideband signal, the method comprising the steps of:
(A) receiving the wideband signal;
(B) getting an interference signal by removing the target signal from the wideband signal;
(C) transforming the interference signal into an inverse interference signal; and
(D) combining the wideband signal with the inverse interference signal to get the target signal.

2. The method according to claim 1, wherein the wideband signal has a first bandwidth, the target signal has a second bandwidth, and the first bandwidth is greater than the second bandwidth.

3. The method according to claim 2, wherein the step (B) comprises:
(B1) inputting the wideband signal to a band pass filter, wherein the target signal passes through the band pass filter, and the interference signal blocks by the band pass filter.

4. The method according to claim 3, wherein the step (B1) further comprises:
down-converting the wideband signal according to a local oscillation signal and then inputting the down converted wideband signal to a low-pass filter; and
inputting an output signal of the low-pass filter to the band pass filter through a circulator, wherein the interference signal is outputted from the circulator.

5. The method according to claim 3, wherein the band pass filter is coupled to a terminator for absorbing an output signal of the band pass filter.

6. The method according to claim 4, further comprising the step of:
up-converting the interference signal according to the local oscillation signal, and inverting the interference signal into the inverse interference signal.

7. The method according to claim 6, wherein the target signal has a center frequency in the wideband signal, and a frequency of the local oscillation signal is lower than the center frequency.

8. The method according to claim 3, wherein a bandwidth of the band pass filter is greater than the second bandwidth and smaller than the first bandwidth.

9. A signal receiver for receiving a target signal existing in a wideband signal, the wideband signal having a first bandwidth, the target signal occupying a second bandwidth of the wideband signal, the signal receiver comprising:
a circulator for receiving the wideband signal and having a first output terminal and a second output terminal;
a band pass filter coupled to the first output terminal of the circulator, wherein the target signal in the wideband signal pass through the band pass filter, and the wideband signal that blocks by the band pass filter form an interference signal to be fed into the first output terminal;
an inverter coupling to the second output terminal of the circulator, receives the interference signal from the second output terminal and transforms the interference signal into an inverse interference signal; and
a combiner for combining the wideband signal with the inverse interference signal to get the target signal.

10. The signal receiver according to claim 9, further comprising:
a local oscillator for generating a local oscillation signal;
a first mixer for down-converting the wideband signal according to the local oscillation signal; and
a first low-pass filter, which is coupled to the first mixer, for receiving the wideband signal and outputting the wideband signal to the circulator.

11. The signal receiver according to claim 9, further comprising:
a terminator, which is coupled to the band pass filter, for absorbing the target signal.

12. The signal receiver according to claim 9, further comprising:
a second mixer, which is coupled to the circulator, for upconverting the interference signal according to the local oscillation signal; and
a second low-pass filter for receiving the interference signal and outputting the interference signal to the inverter.

13. The signal receiver according to claim 9, wherein a bandwidth that can pass through the band pass filter is greater than the second bandwidth and smaller than the first bandwidth.

14. The signal receiver according to claim 10, wherein the target signal has a center frequency in the wideband signal, and a frequency of the local oscillation signal is lower than the center frequency.

15. A wireless multimode wideband receiver, comprising:
an antenna switching module for receiving a wideband signal, which comprises a target signal;
a first duplexer coupled to the antenna switching module;
a second duplexer coupled to the antenna switching module;
a receiver switching module, which is coupled to the antenna switching module, the first duplexer and the second duplexer, for receiving the wideband signal from the antenna switching module, the first duplexer or the second duplexer;
a signal receiver, which is coupled to the receiver switching module, for extracting the target signal from the wideband signal and outputting the target signal; and
a wideband low-noise amplifier, which is coupled to the signal receiver, for amplifying the target signal into an amplified target signal.

16. The receiver according to claim 15, wherein the wideband signal has a first bandwidth, and the target signal occupies a second bandwidth in the wideband signal.

17. The receiver according to claim 15, wherein the first duplexer is a WCDMA duplexer, and the second duplexer is a CDMA2000 duplexer.

18. The receiver according to claim 17, wherein the antenna switching module and the receiver switching module determine a transmitting path of the wideband signal according to the target signal, the wideband signal is transmitted to the receiver switching module through the first duplexer when the target signal is a WCDMA signal, the wideband signal is transmitted to the receiver switching module through the second duplexer when the target signal is a CDMA2000 signal, or otherwise the wideband signal is directly transmitted to the receiver switching module.

19. The receiver according to claim 17, wherein the signal receiver comprises:
a circulator for receiving the wideband signal and having a first output terminal and a second output terminal;
a band pass filter coupled to the first output terminal of the circulator, wherein the target signal in the wideband signal can pass through the band pass filter, and signals that cannot pass through the band pass filter form an interference signal to be fed into the first output terminal;
an inverter, which is coupled to the second output terminal of the circulator, receives the interference signal from the second output terminal and transforms the interference signal into an inverse interference signal; and
a combiner for combining the wideband signal with the inverse interference signal to get the target signal.

20. The receiver according to claim 19, further comprising:
a local oscillator for generating a local oscillation signal;
a first mixer for down-converting the wideband signal according to the local oscillation signal; and
a first low-pass filter, which is coupled to the first mixer, receives the wideband signal and outputs the wideband signal to the circulator.
